(19) United States
(12) Patent Application Publication
(10) Pub. No.: US 2025/0293041 A1
(43) Pub. Date: Sep. 18, 2025

(54) CYCLIC ETCH/DEPOSITION PLASMA PROCESSES USING TUNGSTEN BASED PRECURSOR GAS

(71) Applicant: Tokyo Electron Limited, Tokyo (JP)

(72) Inventors: Alec Dorfner, Albany, NY (US); Minjoon Park, Albany, NY (US)

(21) Appl. No.: 18/603,049

(22) Filed: Mar. 12, 2024

(51) Int. Cl. H01L 21/311; H01J 37/32

(52) U.S. Cl. CPC H01L 21/31116; H01J 37/32926; H01L 21/31144; H01J 2237/332; H01J 2237/334

(57) ABSTRACT

A method of plasma etching a substrate includes cyclically performing a first etch step to etch a target material, the substrate including a patterned mask disposed over the target material and having openings in the patterned mask, performing the first etch step including generating a first plasma from a carbon containing precursor gas and exposing the substrate to the first plasma to form a first passivation layer and etch the target material, the first passivation layer including a polymer material over sidewalls of the openings. And the method further includes cyclically performing a second etch step to remove a portion of the first passivation layer, performing the second etch step including generating a second plasma from a tungsten containing precursor gas and exposing the substrate to the second plasma.

### TECHNICAL FIELD

The present invention relates generally to methods of plasma etching, and, in particular embodiments, to methods, apparatuses, and systems that use a cyclical etch process to remove polymer accumulation and deposit a passivation layer.

### BACKGROUND

Microelectronic device fabrication typically involves a series of manufacturing techniques that include formation, patterning, and removal of a number of layers of material on a substrate. Etch masks may be formed (e.g. deposited, grown) to protect regions of the substrate and allow for pattern transfer via etching. Wet or dry etching processes may be used, with plasma etching processes being an example of a dry etching process.

Etching processes are used in a variety of semiconductor processing areas such as in memory manufacture. One category of etching processes is high aspect ratio (HAR) etching including processes such as high aspect ratio contact (HARC) etches for contact formation. Obtaining a high aspect ratio during etching is useful for a variety of semiconductor processes such as during NAND formation (e.g. 3D-NAND), NOR gate formation, and others.

Defects may occur when transferring a pattern to an underlying layer. For example, the features transferred to the underlying layer may have any number of undesirable defects such as broadening or narrowing, inconsistency in size or location, distortion (e.g. deviation from initial circular shape), and non-vertical sidewalls. Additionally, the edges of the transferred pattern may not be as smooth as the mask pattern, a metric referred to as edge roughness.

Over the course of an etching process polymer can accumulate on the sidewall of the mask. For example, polymer may build up in openings of the mask. This polymer shrinks the aperture, reducing the area through which ions and radicals can pass. The critical dimensions (CDs) of the mask may be undesirably altered by the polymer leading to feature defects. Further, reduced flux of particles to the etch front undesirably slows the etch rate and may exacerbate detrimental effects such as aspect ratio dependent etch-rate (ARDE). Therefore, etching processes which control polymer buildup during the etching process may be desirable.

### SUMMARY

A method of plasma etching a substrate includes cyclically performing a first etch step to etch a target material, the substrate including a patterned mask disposed over the target material and having openings in the patterned mask, performing the first etch step including generating a first plasma from a carbon containing precursor gas and exposing the substrate to the first plasma to form a first passivation layer and etch the target material, the first passivation layer including a polymer material over sidewalls of the openings. And the method further includes cyclically performing a second etch step to remove a portion of the first passivation layer, performing the second etch step including generating a second plasma from a tungsten containing precursor gas and exposing the substrate to the second plasma.

A method of plasma etching a substrate includes cyclically etching a target material with a first plasma, the substrate including a patterned mask disposed over the target material and having openings in the patterned mask, the etching of the target material including forming a first passivation layer including a polymer material over sidewalls of the openings while etching the target material. And the method further includes cyclically etching, with a second plasma, a part of the first passivation layer deposited in the etching of the target material and depositing a second passivation layer including tungsten.

And a plasma etching system includes a plasma chamber, a substrate holder disposed in the plasma chamber and configured to support a substrate, and a controller operationally coupled to the plasma chamber and coupled to a memory storing a program to be executed in the controller, the program including instructions to cyclically generate a first plasma to etch a target material from a carbon containing precursor gas and form a first passivation layer including a polymer material over sidewalls of the openings, and generate a second plasma from a tungsten containing precursor gas to remove a portion of the first passivation layer.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 schematically illustrates an example substrate including a mask material overlying a target material and qualitatively shows polymer buildup over time during a plasma etching process in accordance with embodiments of the invention;

FIG. 2 schematically illustrates an example substrate including polymer material with both primary and secondary facets and another example substrate including polymer material with only a primary facet in accordance with embodiments of the invention;

FIG. 3 schematically illustrates a timing diagram and a corresponding substrate of an example method of etching a target material including multiple first etch steps and second etch steps performed cyclically to remove polymer material accumulated at openings during the first etch steps and passivate the sidewalls during the second etch steps in accordance with embodiments of the invention;

FIG. 4 schematically illustrates an example plasma etching system including a controller operatively coupled to a plasma chamber and configured to deliver a first precursor gas during first etch steps and a second precursor gas during second etch steps in accordance with embodiments of the invention;

FIG. 5 schematically illustrates two timing diagrams of example methods of etching a target material where the total first etch time is the same between the two timing diagrams in accordance with embodiments of the invention;

FIG. 6 schematically illustrates two timing diagrams of example methods of etching a target material where both the total first etch time and the total second etch time are the same between the two timing diagrams, but the number of second etch steps is varied in accordance with embodiments of the invention;

FIG. 7 qualitatively illustrates example dimples exhibiting greater defects contrasted with example dimples exhibiting lesser defects in accordance with embodiments of the invention; and

FIGS. 8A-8B illustrate example methods of etching a target substrate in accordance with embodiments of the invention.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. The various embodiments described herein are applicable in a wide variety of specific contexts. The specific embodiments discussed are merely illustrative of specific ways to make and use various embodiments, and are not to be construed in a limited scope.

Polymer formation often occurs during plasma etching processes. For example, in plasma etching processes that use fluorocarbons as etchants (e.g., compounds having the formula CₓF_{y}, also abbreviated as CFs herein), dissociation within the plasma leads to CF polymer formation. This polymer formation reduces the size of openings in the mask layer resulting in fewer plasma species (e.g. ions and radicals) from reaching the bottom of the mask features. The polymer formation may also passivate sidewalls of the openings, and the passivation may decrease distortions as the plasma etching process progresses.

One major disadvantage of polymer accumulation is to decrease the etch rate during the etching process over time because fewer ions and radicals reach the bottom of mask features (e.g. holes and trenches). The accumulated polymer deflects the plasma species that make it into the mask features from their original trajectory decreasing their verticality. Further, the reduction in etchant species at the bottom of features becomes more dramatic as the aspect ratio increases. Therefore, polymer accumulation at the mask's sidewall (e.g. necking) may also be a primary source of the common undesirable effect of aspect ratio dependent etch-rate (ARDE).

Polymer deflection can also undesirably increase the lateral etch rate relative to the vertical etch rate and cause undesirable effects such as bowing of the sidewalls. The shape of the polymer at the top of the mask (which may be referred to as the secondary facet or 2° facet) typically has an irregular (e.g. rounded, lateral, but non-circular) shape. This irregularity may be projected into underlying layers resulting in undesirable distortion and feature edge roughness (e.g. contact edge roughness (CER)) into the dimple into the underlayer.

Conventional methods for preventing undesirable effects from polymer buildup involve tuning parameters such as high frequency (HF) power, pressure, and relative gas flowrates. For example, gas flowrates may be adjusted as decreasing fluorocarbon (CF) flowrates (e.g. C₄F₆) and/or increasing other flowrates such as oxygen (O₂) flowrates. This may be to make the plasma more lean and alter the gas chemistry of the plasma to include fewer large CF plasma species. For example, smaller CF plasma species may make it further into the mask openings than larger CF species which may tend to stick near the top of the mask.

Yet, this conventional method of gas tuning has many drawbacks. Conventional gas tuning has an inherent tradeoff between increasing overall etch rate and decreasing mask erosion. That is, the gas tuning methods that increase the etch rate also decrease polymer build up. For example, mask selectivity may be undesirably reduced when the etch rate is increased resulting in negative effects that are propagated to underlying layers such as a large bowing critical dimension (CD).

Another conventional method is to use a cyclical etching process comprising a first etch step and a second etch step and switching between the two steps to form the features of the device. The first etch step uses a first precursor gas to form a first plasma to etch the target material to a specific etch depth. After, the polymer accumulation at the openings is etched using the second etch step which uses a second precursor gas to form a second plasma. Unfortunately, the benefit of sidewall passivation by the polymer may be removed during the second etch step of the cyclical conventional method, which may increase distortions in the features being etched in the openings, as well as result in decreased mask height because the passivation of the mask material is removed.

Therefore, removing polymer accumulation in the top region of the mask while maintaining the passivation of the sidewall during etching is desirable. For instance, polymer accumulation in the top region of the mask may cause narrowing of mask openings (small neck CD) through the formation of the 2° facet. However, polymer flux to the sidewall (e.g., oxide sidewall) may be desirable for passivation during the etching. The inventors have determined that the polymer accumulation in the top region of the mask and passivating the sidewall can be removed and a new passivation of the sidewalls may be accomplished by incorporating tungsten containing precursor gas such as tungsten fluoride (WF₆) into the second etch step of the cyclical etching process. In other words, though the second etch step still removes the passivating polymer on the sidewalls, incorporating tungsten containing precursor gas such as WF₆ results in tungsten passivation of the mask and the sidewalls while removing excess polymer accumulation at the openings of the mask. The inventors have determined the inclusion of tungsten containing precursor gas such as WF₆ in the second etch steps aids in the passivation of the sidewalls and the mask which may further improve circularity, improve mask selectivity, decrease distortion, aid in charge accumulation, and decrease contact edge roughness.

The embodiment methods described herein introduce one or more second etch steps for managing polymer accumulation and performing a tungsten passivation of the sidewalls during a plasma etching process. The second etch steps enable first etch steps to have higher polymer flux with the advantage of avoiding clogging, tapering, distortion, and/or CER. In particular, the second etch steps include a second plasma generated from a second precursor gas that includes a second etchant species comprising a tungsten containing precursor gas to remove polymer material without damaging mask material and perform tungsten passivation of the sidewalls. The second etchant species is different than a first etchant species included in a first precursor gas used to generate a first plasma for first etch steps. For example, the second etchant species may further comprise oxygen (i.e. oxygen-containing compounds). Bias power may be applied during the second etch step to increase ion verticality for improved removal of the secondary facet. The target material may be a dielectric such as an oxide, a nitride, or a stack thereof (e.g. ONO). The mask material may be a hard mask material such as silicon nitride and may include carbon. For instance, the mask material may be an amorphous carbon layer (ACL).

Through the implementation of a cyclic etching process, polymer accumulation can be advantageously controlled without directly impacting sidewall passivation during the second etch step. In many etching applications (e.g. HAR etches such as a HARC etch), polymer accumulation may be the driving force behind such undesirable effects such as distortion and CER. That is, distortion and CER are persistent issues in dielectric HARC etch processes. Consequently, controlling polymer buildup during the cyclical etching process has the advantages of controlling distortion and CER.

An additional advantage is the ability to consistently and selectively remove the 2° facet of the polymer buildup (i.e., the secondary rounded irregular facet). This is beneficial for the desirable sidewall passivation afforded by tungsten passivation of the sidewall during the second etch step while removing the undesirable polymer buildup at the top of the mask features. Removing the 2° facet also advantageously reduces the amount of plasma species (e.g. ions) that are deflected into the sidewall during the first etch steps. With fewer species impacting the sidewalls, lateral etching effects such as undesirable bowing can also be reduced.

Variation in second etch parameters can provide optimization benefits for a given cyclical etching process. Second etch chemistry can be tailored independently from the first etch chemistry as needed (e.g. to react more aggressively with the polymer or to increase ion sputtering). The duration of each second etch step and/or the total second etch duration for the entire cyclical etching process may also be tailored to optimize etch rate, total etch time, bottom to top ratio (B/T ratio), dimple CD, distortion, and contact edge roughness (CER) improvements, among others.

The inventors have also determined that, in certain embodiments, the effectiveness of a second etch step at removing polymer may be subject to diminishing returns as the second etch duration is increased. That is, an early portion of each second etch step may have the largest impact on mitigating negative effects such as B/T ratio, distortion, and CER. As the second etch duration is increased, the added benefit is smaller and smaller until no benefit is obtained by extending the second etch duration (e.g. because all of the polymer is removed and/or there are chamber effects, substrate cooling, etc.).

As a result, when multiple second etch steps are utilized, there may be additional control over the efficiency of the cyclical etching process. For instance, including more second etch steps of shorter duration can advantageously maximize the highly effective early portion of each second etch step and avoid second etch step inefficiency. For example, the second etch step towards the end of the etching process may be shorter than the second etch steps at the beginning of the etch process. As one example, the second etch step towards the end of the etching process may have a time duration that is 30% to 70% of a time duration of the second etch steps at the beginning of the etch process. Further, controlling the frequency of second etch steps for a given cyclical etching process carries the benefit of tuning the second etch steps to be applied when there is an optimal amount of polymer accumulation to achieve the maximum benefits.

Other conventional methods have used cleaning steps in contexts other than those described here. For example, polymer buildup is a difficulty encountered in a variety of processes, including other etching processes. Accordingly, conventional etching methods have used cleaning steps to remove polymer buildup with varying success. For example, in the specific example of a silicon oxynitride (SiON) mask, CF₄-based cleaning steps have been used to remove silicon oxide or silicon oxynitride buildup during ACL etches and silicon etches (to form shallow trench isolation).

However, the inclusion of fluorocarbons such as CF₄ in the flash steps described herein would often be counterproductive, working towards the opposite result (polymer accumulation rather than polymer removal). Further, many conventional cleaning steps do not use bias power during the cleaning step (e.g. to avoid substrate damage) and are consequently less effective in general and at targeting formations such as the secondary facet. Conventional cleaning steps may also use cleaning step chemistry that cannot be allowed to mix with the etch step chemistry requiring the plasma chamber to be evacuated between every step, which increases the total fabrication time.

The methods described herein improve upon these conventional methods by incorporating one or more features such as tungsten-based, fluorocarbon-free second etch chemistry, bias power during the second etch step, heavy inert gas bombardment, purge-free gas switching, selectivity of the first etch target (e.g. oxide, ONO, etc.), and enhanced control over polymer accumulation by tailoring second etch frequency, first-to-second etch ratio, total second etch time, and total etch time, among others.

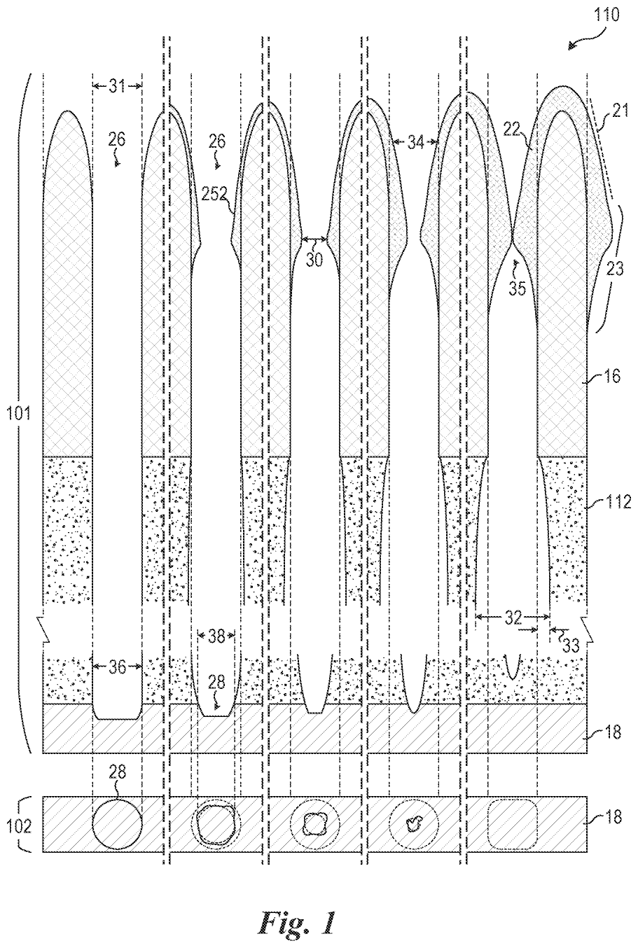

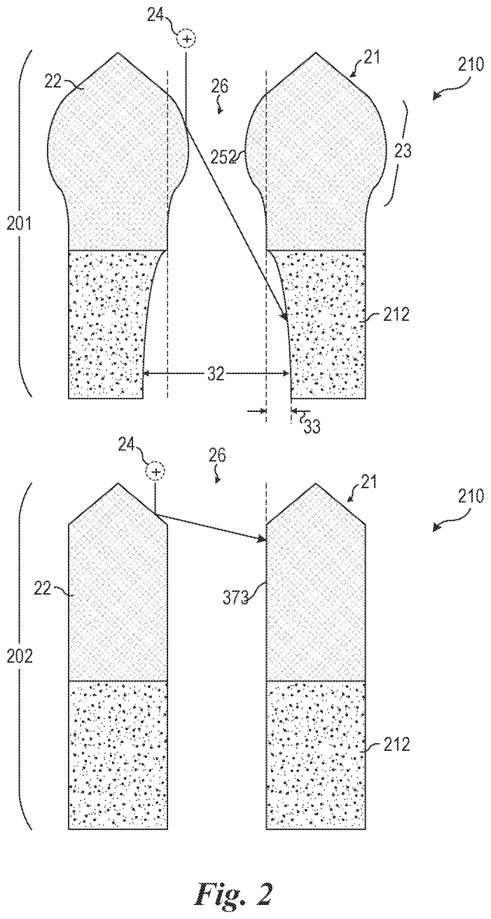

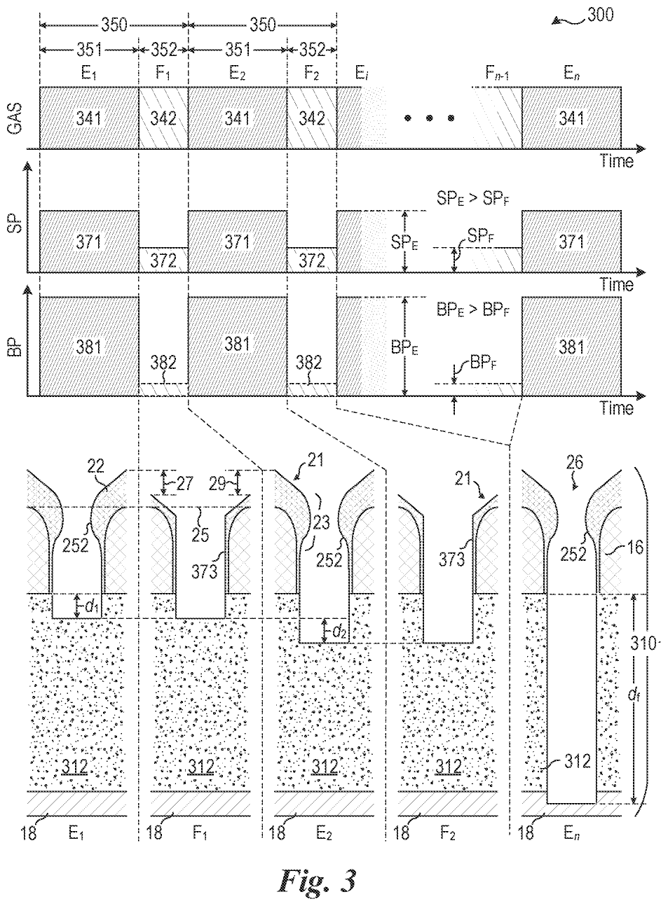

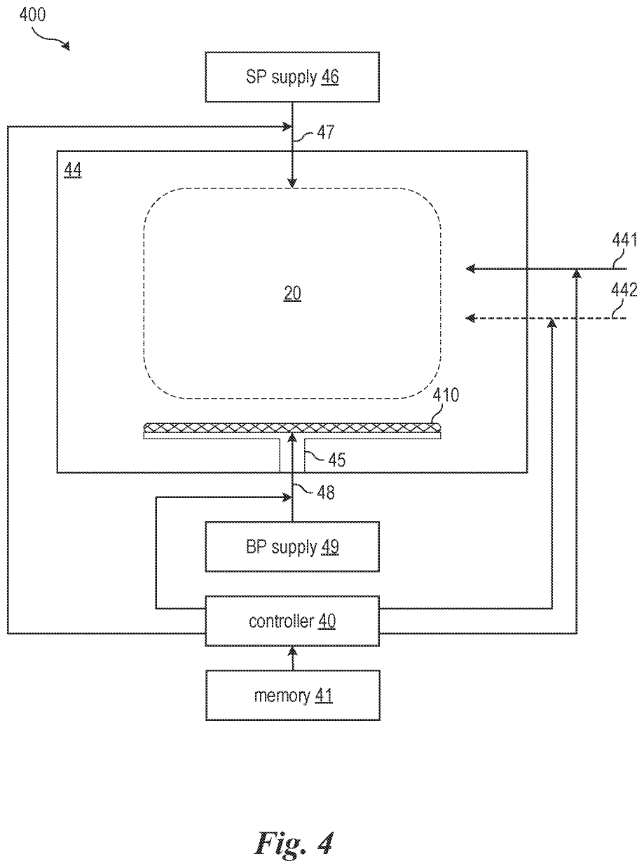

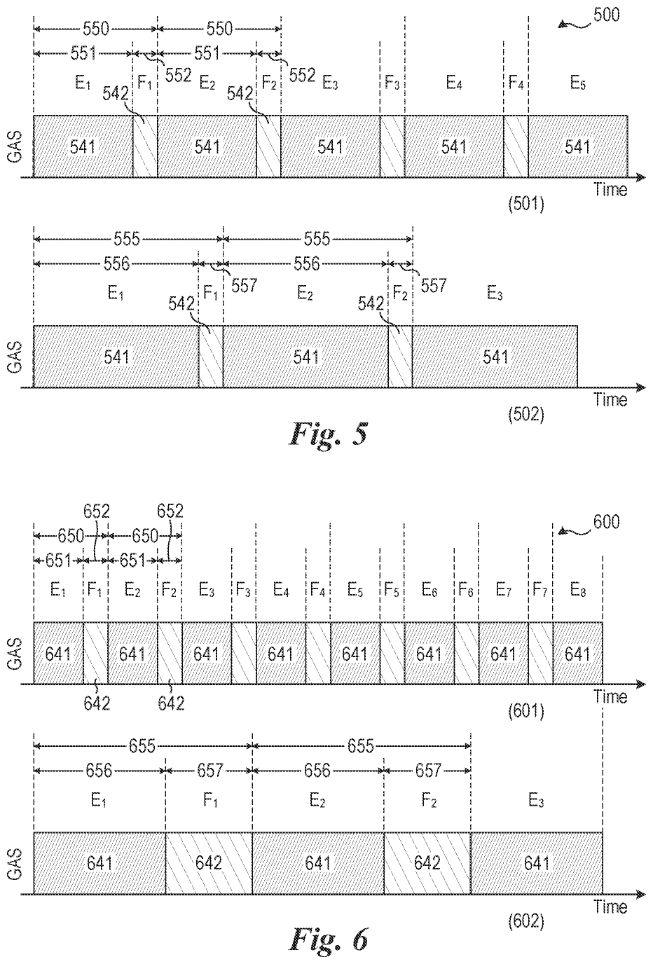

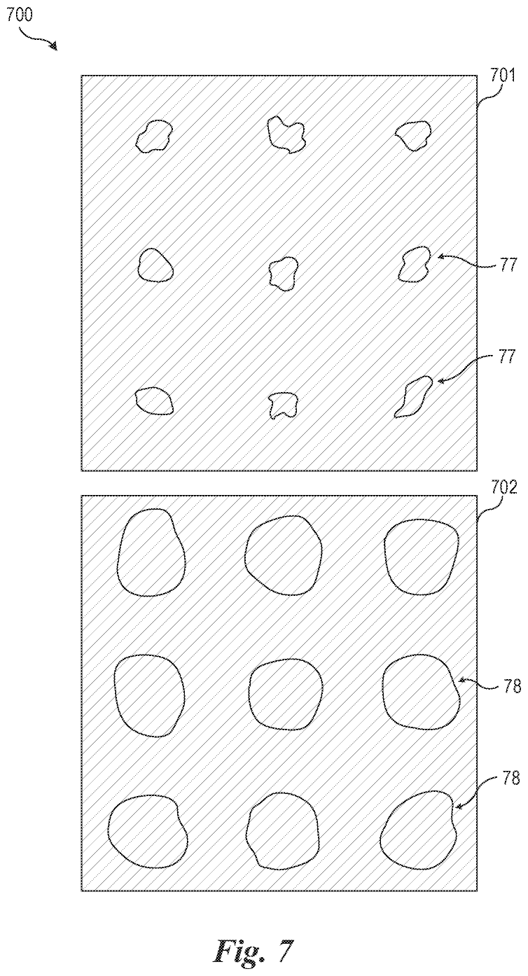

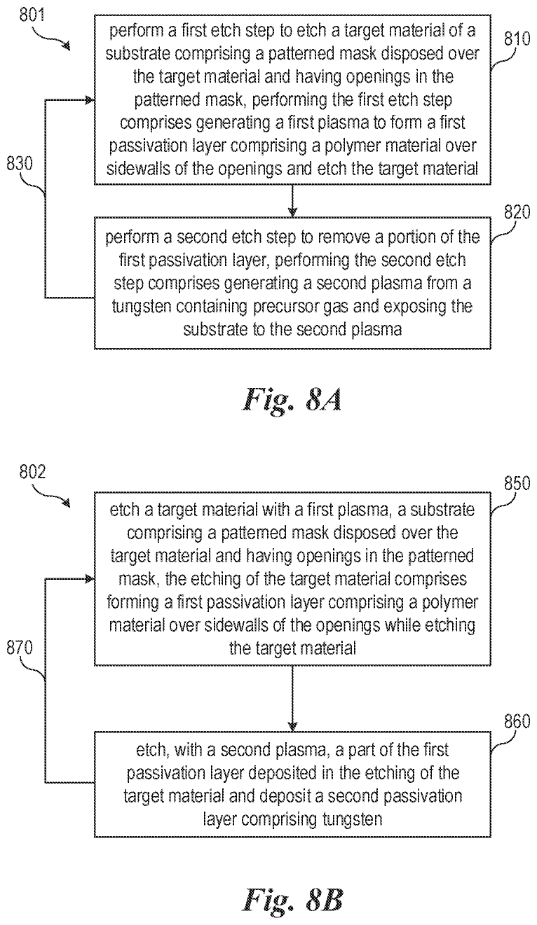

Embodiments provided below describe various methods, apparatuses and systems of plasma etching, and in particular, to methods, apparatuses, and systems that use a cyclical etching process comprising a first etch step and a second etch step where the second etch step comprises WF₆ and is used to remove polymer and passivate sidewalls during a plasma etching process. The following description describes the embodiments. FIG. 1 is used to describe an example substrate. FIG. 2 is used to describe two example substrates that are contrasted by the effects of a secondary facet of a polymer material. An example method of etching a target material is described using FIG. 3. An example plasma etching system configured to perform methods of etching a target material is described using FIG. 4. Two more example methods of etching a target material that demonstrate the effects of holding total first etch time and total second etch time constant are described using FIGS. 5 and 6. FIG. 7 is used to qualitatively illustrate differences between greater defects and lesser defects in dimples. And FIGS. 8A-8B are used to illustrate two other example embodiment methods of cyclically etching a target material of this disclosure.

FIG. 1 schematically illustrates an example substrate including a mask material overlying a target material and qualitatively shows polymer buildup over time during a plasma etching process in accordance with embodiments of the invention.

Referring to FIG. 1, a side view 101 and a top view 102 show a substrate 110 comprising a mask material 16 overlying a target material 112. The mask material 16 is patterned to form openings 26 that are used to transfer a desired pattern from the mask layer including the mask material 16 into the target material 112 and optionally an underlying layer 18 beneath the target material 112. The substrate 110 may be any suitable substrate, such as an insulating, conducting, or semiconducting substrate with one or more layers disposed thereon. One example category of possible substrates would be one of the many types of semiconductor wafer (silicon, silicon-on-insulator, germanium, gallium arsenide, etc.).

This configuration may represent a general etching process and is not limited to any specific materials or patterns. For example, the target material 112 may be any suitable material, but is a dielectric in various embodiments. In one embodiment, the target material 112 is a dielectric that includes an oxide. For example, the dielectric may include silicon dioxide (SiO₂). In various other embodiments, other oxides may be used, such as aluminum oxide (Al₂O₃, commonly referred to as sapphire), and others. In one embodiment, the dielectric includes a nitride, such as silicon nitride (Si₃N₄).

The target material 112 may be a homogeneous material (such as SiO₂) or it may be a stack of any number of materials. In some embodiments, the target material 112 is a stack including an oxide and a nitride, and is an alternating stack of oxides and nitrides (often referred to as an ONO stack). For example, the target material 112 may be an ONO stack including tens to hundreds of alternating SiO₂ and Si₃N₄ layers. Such a configuration may be used in various applications, such as a HARC etch for memory (e.g. 3D-NAND, DRAM, etc.). In the specific example of a HARC etch, the underlying layer 18 may be a semiconductor layer (e.g. a device layer) with which electrical contact is being made using the plasma etching process.

The mask material 16 may also be any suitable material, such as a material with properties that enable the patterned mask material to protect underlying portions of the target material 112 while exposed portions of the target material 112 (i.e. in the openings 26) are etched away during a plasma etching process. In various embodiments, the mask material 16 is a hard mask material, such as for HAR etches. In some embodiments, the mask material 16 includes carbon and is an ACL. Other possible materials for the mask material 16 include polysilicon, a tungsten-containing material, among others. In the specific example where the target material 112 is a dielectric, the mask material 16 may be chosen to be resistant to fluorocarbon (CF) chemistry as fluorocarbons (especially higher molecular weight fluorocarbons having at least two carbon atoms) may be used to etch the target material 112.

As time passes during a first etch step of the cyclical etching process, a polymer material 22 builds up on the mask material 16, especially at the tops of features, such as on and around the openings 26. Further, the polymer material 22 may also passivate sidewalls of the mask material 16 and the target material 112 and form a first passivation layer 252 comprising polymer over the mask material 16 and the sidewalls of the target material 112. FIG. 1 shows several examples of the polymer material 22 accumulating around the openings 26 to varying degrees. Each of the examples may represent a different first etch step in a cyclic process. Possible qualitative effects of different average levels of polymer buildup during the etching process are illustrated at the bottom of FIG. 1.

There are many different types of polymer material 22 that may build up depending on the properties of the target material 112 and the types of first precursor gases used to generate the first plasma. In various embodiments, the polymer material 22 is an organic polymer (i.e. including carbon). For example, the carbon may be introduced from fluorocarbon etchants (e.g. C₄F₆, C₄F₈, C₃F₈, CHF₃, CH₂F₂, CH₃F, etc.) or may come from the mask material 16, such as for ACL masks. In some cases, the presence of fluorocarbons during the first etch step interact with various materials of the substrate 110 to form the polymer material 22.

As shown, the polymer material 22 may accumulate at the openings 26 of the mask material 16 in a particular way that gives rise to a substantially flat primary facet 21 and a rounded secondary facet 23 that bulges out into the openings 26. Initially, the openings 26 are clear and have a mask width 31 allowing for the maximum flux of plasma species of the first plasma to enter the openings 26 and reach the bottom of the features being etched. However, over time the polymer material 22 builds up and reduces the minimum size of the openings 26, which is referred to as the NCD 30 (neck CD). As the first etch step progresses, the NCD 30 becomes smaller and smaller relative to the mask width 31 and a variety of undesirable effects may occur.

For example, in an extreme case the NCD 30 becomes zero and the openings 26 close (as shown by arrow 35). This can cause the etching of the target material 112 to stop and the desired etch depth (e.g. the underlying layer 18) may be unreachable. While this worst-case-scenario may not always happen (depending on several factors related to the first etch step parameters), the polymer material 22 cannot be prevented from accumulating using first etch step parameters for many plasma etching processes such as those using fluorocarbons. Moreover, even small amounts of polymer accumulation may have undesirable effects on the results of the cyclical etching process.

For instance, various CDs may be affected by polymer accumulation, such as TCD 34 (top CD, measured near the top of the openings 26, such as between 80% and 100% of the feature height), BCD 36 (bottom CD, similarly measured near the bottom of the openings 26, such as between 0% and 20% of the feature height), and DCD 38 (dimple CD, such as measuring the mean diameter or the maximum size of a dimple 28 formed in the underlying layer 18), among others. One specific CD that may be affected and lead to the degradation of other CDs is bowing CD 32, resulting from plasma species being deflected by, for example, the secondary facet 23. The bowing CD 32 is the maximum width of the feature and may also be measured per side (shown as per side bow 33).

In practice, the dimple 28 will deviate from the ideal shape and size of the features that the patterned mask material 16 is designed to transfer. Minimizing these deviations is desirable and may be achieved by reducing the amount of time that polymer buildup is present in the openings 26. Some common measures of deviation for the dimples 28 are distortion (which can be expressed various ways that measure the uniformity of the dimple 28 such as ellipticity expressed as minimum diameter divided by maximum diameter or minimum radius divided by maximum radius), and CER which is a measure of the smoothness of the boundary of the dimple 28 (e.g. expressed as a three-sigma deviation of the radius or the diameter). As shown, the dimple 28 becomes more and more distorted and rough as the polymer material 22 builds up in the openings 26.

FIG. 2 schematically illustrates an example substrate including polymer material with both primary and secondary facets and another example substrate including polymer material with only a primary facet in accordance with embodiments of the invention. The substrates of FIG. 2 may be a specific implementation of other substrates described herein such as the substrate of FIG. 1, for example. Similarly labeled elements may be as previously described.

Referring to FIG. 2, a substrate 210 includes a polymer material 22 overlying a target material 212 as before. Although an example shape of the polymer material 22 with the primary facet 21 and the secondary facet 23 is shown, the shape of the polymer may vary while still having the primary facet 21 and the secondary facet 23. Accordingly, a conceptually simplified version of the polymer material 22 is provided to highlight fundamental effects of the accumulation of the polymer material 22 at the openings 26.

Here and in the following a convention has been adopted for brevity and clarity wherein elements adhering to the pattern [x10] where ‘x’ is the figure number may be related implementations of a substrate in various embodiments. For example, the substrate 210 may be similar to the substrate 110 except as otherwise stated. An analogous convention has also been adopted for other elements as made clear by the use of similar terms in conjunction with the aforementioned numbering system.

In the first example 201, the polymer material 22 has accumulated and formed a shape that includes both a primary facet 21 and a polymer material 22. Notably, the secondary facet 23 extends into the openings 26 and have a rounded surface (as opposed to the substantially linear surface of the primary facet 21). In various embodiments, the primary facet 21 can be entirely polymer, include mask material, or be entirely mask material (e.g. if the polymer that accumulates at the top of the mask is continuously etched away).

During the first etch step, ions 24 are accelerated toward the substrate 210 (i.e. given vertical velocity relative to the substrate 210) with the intent of introducing a vertical flux of the ions 24 to the bottom of the feature and increase the etch depth. However, as the secondary facet 23 grows the ions 24 may be deflected with increasing probability resulting in fewer ions 24 reaching the bottom of the feature and more ions 24 impacting the sidewalls of the feature. This is one source of undesirable bowing effects (bowing CD 32 and per side bow 33 as shown), which motivates the benefits of sidewall passivation to help mitigate distortions.

In the second example 202, some of the polymer material 22 still remains, but only the primary facet 21 is present (i.e. the secondary facet 23 has been removed using a second etch step that also deposited a second passivation layer 373 comprising tungsten). In this scenario, fewer of the ions 24 are deflected into the sidewalls and there is a larger vertical flux of ions 24 to the bottom of the feature. Consequently, this may be a desirable goal for polymer removal that has additional advantages over simply removing all of the polymer. For example, polymer that that does not negatively affect the etching process remains at the top of the openings 26 and protects the mask material (not shown) from eroding during the first etch step. In another embodiment, the first passivation layer 252 comprising polymer is removed using the second etch step and the second passivation layer 373 comprising tungsten is deposited to protect the mask material. Some amount of polymer or tungsten as a first or second passivation layer is often desirable to improve selectivity, and to passivate the sidewalls to reduce distortions.

FIG. 3 schematically illustrates a timing diagram and a corresponding substrate of an example method of etching a target material using a cyclical etch process that switches between a first etch step to etch the target material and a second etch step to remove polymer material accumulated at openings during the first etch step and to passivate the sidewalls and form a second passivation layer in accordance with embodiments of the invention. The method of FIG. 3 may be performed using any substrate as described herein, such as the substrates of FIGS. 1 and 2, for example. Similarly labeled elements are as previously described.

Referring to FIG. 3, a method 300 of etching a target material 312 (such as a dielectric) using different plasmas includes repeatedly performing a cycle 350 that alternates between a first etch step Eᵢ and a second etch step Fᵢ (which may also be called a flash step) until n first etch steps have been performed (e.g. cyclically performing a series of steps that make up the cycle 350 until n first etch steps have been performed). Although the last cycle (e.g. the n^{th} cycle) is shown as not including the second etch step Fₙ, a final second etch step may be included if desired. The number of cycles n may be any suitable value, and may depend on a variety of factors such as the desired etch depth d_{f}, the rates of accumulation and removal of the polymer material 22, the etch rate, the chemistry (both first etch chemistry and second etch chemistry), and others.

The first etch step Eᵢ is performed for a first etch step duration 351 during which a first precursor gas 341 is provided near a substrate 310 that includes the target material 312. A first plasma is generated from the first precursor gas 341 (e.g. by applying first etch source power 371 (SP) at a first etch source power level SPE). The first precursor gas 341 includes a first etchant species with chosen selectivity to etch a target material 312 exposed in the openings 26 of a patterned mask material 16. For example, the first etchant species may have greater reactivity toward the target material 312 (e.g. a dielectric such as an oxide) than toward the mask material 16 (e.g. a hard mask material such as an ACL).

The effects of a first etch step E₁ are shown in FIG. 3. During the first etch step E₁, bias power (BP) may be applied as etch bias power 381 at a first etch bias power level BP_{E} to impart vertical velocity to charged species of the first plasma (such as positive ions of the first etchant species). The first plasma species including the ions etch the target material 312 to a first etch depth d₁ during the first etch step duration 351. As previously discussed, a polymer material 22 is accumulated on the mask material 16 forming a shape that reduces the size of the openings 26 and includes a primary facet 21 and a secondary facet 23. The polymer material 22 may also passivate the sidewalls of the target material 312 and the patterned mask material 16 and form a first passivation layer 252 comprising polymer.

The second etch step Fᵢ (or the flash step) is performed for a second etch step duration 352. During the second etch step duration 352, a second precursor gas 342 is provided near the substrate 310 to remove polymer material 22 accumulated at the openings 26 during the first etch step Eᵢ, and to passivate the sidewalls of the target material 312 and form a second passivation layer 373 comprising tungsten to improve distortion. In an embodiment, the second etch step Fᵢ may also replace the first passivation layer 252 of polymer that had been deposited during the first etch step E; from the accumulation of the polymer material 22 on the sidewalls to further control distortions of the target material 312. Further, in those same embodiments, the replacement of the first passivation layer 252 of the sidewalls with the second passivation layer 373 by the deposition of materials of a second plasma species may also reach the bottom of the feature being formed, which may reduce charge accumulation at the etch front and thus further reduce bending and other charge accumulation driven defects.

A second plasma is generated from the second precursor gas 342 (e.g. by coupling a second etch source power 372 to the second precursor gas 342 at a second etch source power level SPF). As shown, in various embodiments, SPF is less than SPE. This may be, for example, to prevent damage to materials other than the polymer material 22 such as the mask material 16 (or even to prevent excessive damage to the polymer material 22 because, as mentioned above, some polymer or other passivating material is often beneficial to the etching process). In various embodiments, switching from the first etch step Eᵢ to the second etch step Fᵢ comprises stopping the first plasma and the first precursor gas, then pumping in the second precursor gas and igniting the second precursor gas into the second plasma.

The second precursor gas 342 includes a second etchant species that is chosen to interact with the polymer material 22 such that the second etchant species works to remove the polymer material 22 during the flash step Fᵢ and replaces the first passivation layer 252 on the sidewall of the target material 312 with the second passivation layer 373. For instance, the second etchant species may react with the polymer material 22. Additionally, the second etchant species may have some selectivity to the polymer material 22 such as having greater reactivity toward the polymer material 22 than toward the target material 312. The second etchant species removes the passivating polymer on the sidewalls of the openings 26 during the second etch step, and deposits a tungsten passivation layer (the second passivation layer 373) in place of the polymer passivation layer (the first passivation layer 252). Thus, the method 300 illustrated in FIG. 3 maintains the benefits of the polymer passivation by using a tungsten containing precursor gas such as WF₆ in the second etchant species to form tungsten passivation of the mask material 16 and the target material 312.

In all embodiments, the second precursor gas 342 comprises a tungsten containing precursor gas in a mixture with other gases. The second precursor gas 342 may comprise a mixture comprising a precursor gas containing a halogen and tungsten, e.g., tungsten fluoride (WF₆). In certain embodiments, the second precursor gas 342 comprises a precursor gas containing tungsten, chlorine, and fluorine. As described above, the tungsten (W) aids in charge mitigation, and forms the second passivation layer 373 over sidewalls of the target material 312. The inclusion of tungsten fluoride (WF₆) in the second precursor gas 342 also aids in diminishing distortions of features being formed in the substrate while clearing the openings 26 of the accumulated polymer material 22. In an embodiment, the second precursor gas 342 comprises oxygen (O₂), carbonyl sulfide (COS), and tungsten fluoride (WF₆). In another embodiment, the second precursor gas 342 comprises oxygen (O₂), and tungsten fluoride (WF₆). And in another embodiment, the second precursor gas 342 comprises nitrogen (N₂), hydrogen (H₂), and tungsten fluoride (WF₆).

The effects of the first second etch step F₁ are also shown. During the first second etch step F₁, bias power may also be applied as second etch bias power 382 at a second etch bias power level BP_{F}. Some amount of bias power may advantageously impart vertical velocity to ions of the second plasma and improve the selectivity of the second etch step to the secondary facet 23 (e.g. the rounded protrusions of the secondary facet 23 are less stable than the supported primary facet 21 and therefore may be more susceptible to bombardment effects knocking polymer of the secondary facet 23 free). However, as with the source power (and to a greater degree in many embodiments) BP_{F} is less than BP_{E}.

The overall effect of the second etch step Fᵢ is to remove polymer material 22 and deposit the second passivation layer 373 comprising tungsten (W) on the sidewalls of the target material 312 and the mask material 16. The second passivation layer 373 on the mask material 16 may also prevent mask height reduction of the mask material 16. Specifically, the secondary facet 23 of the polymer material 22 may be removed or reduced such that the openings 26 are widened to be closer to the original mask width (e.g. the NCD of the openings 26 is increased during the flash step) while improving distortions of the target material 312 using the resulting second passivation layer 373 comprising tungsten (W). The primary facet 21 may also be affected. Advantageously, there is no requirement to fully remove the primary facet 21 (and indeed it may be beneficial to leave it along with, for example, some first passivation layer 252 comprising polymer and some second passivation layer 373 comprising tungsten on sidewalls as shown). In this qualitative example, the polymer height reduction 27 does not result in the original mask material 16 being exposed (i.e. the mask height may be protected by the second passivation layer 373 that results from the second etch step). Additionally, even if the primary facet 21 is fully removed, its prior presence combined with the preferential removal of the secondary facet 23 and the second passivation layer 373 of the sidewalls may advantageously reduce or limit mask height reduction during the first etch step and the second etch step.

As shown, the second first etch step E₂ results in the target material 312 being etched to a second etch depth d₂ and accumulation of the polymer material 22 to form the familiar structure with a primary facet 21 and a secondary facet 23. The polymer buildup may also result in a polymer height increase 29 (conceptually shown as equal to the polymer height reduction 27, but of course may be less or more). The second etch step F₂ then again removes the secondary facet 23 and some of the primary facet 21 and the first passivation layer 252 and forms another second passivation layer 373 on the sidewalls of both the mask material 16 and the target material 312. The cycle 350 is repeated to achieve the desired etch depth.

In this ideal situation there will never be a mask removal cost for repeatedly performing the second etch step. However, in practice, the rate of polymer accumulation may be less than the rate of polymer removal and mask removal may eventually occur, but the second passivation layer 373 comprising tungsten may help to reduce mask removal. For example, the inventors have determined that at least for some conditions, up to 10 second etch steps may be performed with no selectivity cost, but these results will heavily depend on the specific details of a given application. Other benefits of the second passivation layer 373 comprising tungsten on the sidewalls are the sidewall smoothness is improved and the selectivity of the mask material 16 may be improved. In embodiments, polymerization of gases occurs constantly over the course of the first etch step to form the first passivation layer 252. In various embodiments, the second passivation layer 373 forms as a result of a surface reaction between WF₆ and the mask material 16. Further, the WF₆ may react with SiN and form WN, passivating the upper portion of the target material 312, and gas phase reactions between WF₆ and other gases in the plasma (such as N₂, CO, O₂, etc.) can also occur, leading to further deposition of W on the features to form the second passivation layer 373.

The cyclical etching process may be terminated after a desired final etch depth de is reached. For applications where the goal is to breach an underlying layer 18 with the etch, the method 300 of etching the target material 312 may end once the desired pattern is transferred into the underlying layer 18 after n first etch steps (such as a semiconductor device layer during a HARC etch, for example). Several potential advantages achieved as a final result of implementing the method 300 is improved distortion, CER, DCD (dimple CD), and bowing CD. Additionally, the method 300 can also reduce ARDE due to the increased average NCD (neck CD) allowing first etchant species to more consistently reach the bottom of the features during the cyclical etching process. And further, the addition of WF₆ may improve mask material 16 selectivity.

As shown in this specific example, the method 300 may be performed with no purge step between the first etch steps and second etch steps (e.g. without evacuating the plasma chamber between steps). This may advantageously reduce the overall process time and simplify the fabrication process. The lack of purge steps may be made possible, for example, because of the chosen first etch chemistry, second etch chemistry, and etch parameters such as power settings, step durations, and the materials of the substrate 310.

While optimized recipes will derive some benefit from the method 300, un-optimized recipes could derive even more benefit because the ability to effectively remove polymer may allow for more polymer to be generated during first etch steps with fewer consequences. As a result, recipes may advantageously be optimized in a different way; optimization may take into account that more polymer can be generated and other aspects may be optimized such as etch rate or selectivity.

Various second etch step options may increase the time efficiency of the second etch step, or the cyclical etching process as a whole. For example, the inventors have determined that the greatest benefit to removing the secondary facet is during the beginning portion of the second etch step. This may be, for example, because the top portion of the secondary facet is rapidly removed which quickly allows more ions to enter the opening without being deflected. Additionally, the inventors have observed that under certain conditions there may be diminishing returns for second etch steps that are too long. For example, benefits to CDs, distortion, CER, and ARDE may be lessened (or even harmed). Longer second etch steps of course also result in longer overall process times.

In various embodiments, the second etch step duration 352 is less than about 40 s and is less than about 20 s in some embodiments. In some applications, 20 s may strike a desirable balance and so in one embodiment, the second etch step duration 352 is about 20 s. However, more rapid second etch steps also appear to be beneficial (as opposed to fewer, longer second etch steps). Therefore, in other embodiments, the second etch step duration 352 is less than about 10 s and is about 10 s in one embodiment.

The number of second etch steps performed during the cyclical etching process may influence the degree of benefit for nearly all parameters. For example, distortion, DCD, BT ratio (bottom-to-top ratio: BCD/TCD), and CER may all improve with a greater raw number of second etch steps. Some metrics such as bowing may derive general benefit from the second etch step through the second passivation layer on the sidewalls of the target material 312 and the mask material 16, but may not further improve by simply adding more second etch steps.

FIG. 4 schematically illustrates an example plasma etching system including a controller operatively coupled to a plasma chamber and configured to deliver a first precursor gas during first etch steps and a second precursor gas during second etch steps in accordance with embodiments of the invention. The plasma etching system of FIG. 4 may be used to perform any of the methods described herein, such as the method of FIG. 3, for example. Similarly labeled elements may be as previously described.

Referring to FIG. 4, a plasma etching system 400 includes a controller 40 operatively coupled to a plasma chamber 44 and a memory 41 coupled to the controller 40 and storing a set of instructions (or a program) to be executed by the controller 40. The instructions when executed cause the controller 40 to provide a first precursor gas 441 and a second precursor gas 442 in the plasma chamber 44. The instructions when executed further may cause the controller 40 to cyclically perform the first etch step by providing the first precursor gas 441 and the second etch step by providing the second precursor gas 442 without evacuating the plasma chamber 44 between steps. The memory 41 may be any suitable device for storing the instructions to be executed by the controller 40.

The controller 40 is further coupled to a source power supply 46 that is configured to couple source power to gas within the plasma chamber 44. For example, the source power supply 46 may be any suitable type of source power supply such as an RF power supply. The source power supply 46 is configured to generate plasma 20 in the plasma chamber 44 by igniting either the first precursor gas 441 into a first plasma or the second precursor gas 442 into a second plasma. The plasma 20 may be an inductively coupled plasma (ICP), capacitively coupled plasma (CCP), or any other desired type.

A substrate 410 including patterned mask material with openings that expose a target material may be loaded in the plasma chamber 44. A substrate holder 45 may be included in the plasma chamber 44 to support the substrate 410. The substrate holder 45 may be any suitable type of holder including mechanical, vacuum, or electrostatic chucks. The controller 40 may be operationally coupled to a bias power supply 49 that is in turn coupled to the substrate 410 (e.g. via the substrate holder 45) and configured to deliver bias power 48 at the substrate 410.

The source power supply 46 may be configured to deliver higher wattage power during the first etch step and lower wattage power during the second etch step. In various embodiments, the SPE is between about 3 kW and about 8 kW and is between about 4 kW and about 5 kW in some embodiments. In contrast, during the second etch step, the source power supply 46 is configured to deliver lower power. In various embodiments, the SPF is between about 500 W and about 2 kW, and is about 1 kW in one embodiment.

Similarly, the bias power supply 49 may also be configured to deliver higher wattage power (e.g. even higher than the source power) during the first etch step and lower wattage power during the second etch step. In some embodiments, BP_{E} is greater than about 2 kW while BP_{F} is less than about 500 W. For example, the BP_{E} is between about 10 kW and about 25 kW in various embodiments and between about 15 kW and 18 kW in some embodiments. In contrast, BP_{F} is between about 100 W and about 1 kW in some embodiments, and is about 200 W in one embodiment.

The bias power supply 49 may also be an RF power supply and may be configured to provide RF power in the low frequency (LF) to medium frequency (MF) range. In one embodiment, the bias power supply 49 is configured to supply RF bias power at about 400 kHz. For example, during the second etch step, the bias power 48 may be provided to the substrate 410 with an RF frequency of 400 kHz and a bias power (SPF) of about 200 W. Other bias power strategies may also be employed, such as square waveforms (which may be referred to as high energy rectangular bias).

The first precursor gas 441 includes a first etchant species that is selective to the target material. For example, in the specific application of a dielectric etch including an oxide, the first etchant species may be a fluorocarbon having the chemical formula CₓF_{y}. In various embodiments, the fluorocarbon is a higher molecular weight fluorocarbon having at least two carbon atoms, and (as a result) a higher ratio of carbon to fluorine. For example, the first etchant species may be CF₄, C₄F₈, C₅F₈, C₂F₆, C₄F₆, C₅F₆, and others.

The second precursor gas 442 includes a second etchant species that functions as an etchant and comprises WF₆. The second etchant species targets organic material such as the polymer material. In an embodiment, the second etchant species comprises oxygen (O₂), carbonyl sulfide (COS), and tungsten fluoride (WF₆). In another embodiment, the second etchant species comprises oxygen (O₂), and tungsten fluoride (WF₆). And in another embodiment, the second etchant species comprises nitrogen (N₂), hydrogen (H₂), and tungsten fluoride (WF₆).

The second precursor gas 442 may also include various additional components such as inert species or additives intended to improve desired results. In one embodiment, the second precursor gas 442 includes carbonyl sulfide (COS) and tungsten fluoride (WF₆). For example, including COS may further reduce bowing leading to other beneficial effects.

FIG. 5 schematically illustrates two timing diagrams of example methods of etching a target material where the total first etch time is the same between the two timing diagrams in accordance with embodiments of the invention. The methods of FIG. 5 may be specific implementations of other methods described herein, such as the method of FIG. 3, for example. Similarly labeled elements may be as previously described.

Referring to FIG. 5, a method 500 is similar to the method 300, but demonstrates varying the number of second etch steps without varying the total first etch time. Source power and bias power may also be varied as in the method 300, but are not shown here for simplicity. Such a scenario may be desirable when the total first etch time desired is known or capped and the goal is to optimize other effects with the appropriate number of second etch steps. As shown, a first configuration 501 repeats a cycle 550 that includes a first etch step using first precursor gas 541 and a first etch step duration 551 (or first duration) along with a second etch step using a second precursor gas 542 and a second etch step duration 552 (or second duration). The first configuration 501 has five first etch steps and four second etch steps, as shown.

In the second configuration 502, the number of second etch steps is reduced to two resulting in only three first etch steps. To keep the total first etch time the same, the first etch steps are lengthened to a first etch step duration 556 resulting in a longer cycle 555. The second etch step duration 557 may be the same or different depending on the desired outcome. Here, the second etch step duration 557 is the same as the second etch step duration 552, which may be desirable when an optimal second etch step duration is determined and only the number of second etch steps is being optimized.

Additionally, the duration of both the first etch step and the second etch step may be dynamically changed in some cases which may be useful when there are effects that change as the etch depth increases or time passes during the cyclical etching process.

A related parameter that may have similar effects as the number of second etch steps is the second etch step frequency. In particular, as the number of second etch steps is increased, the frequency of the second etch steps (equal to 1 over the cycle or period) typically also increases because the total first etch time remains mostly the same for a given process. As shown in the first configuration 501 and the second configuration 502, the second etch step frequency is increased as the number of second etch steps is increased. In various embodiments, the second etch step frequency is greater than about one second etch step per two minutes. In one embodiment, the second etch step frequency is greater than about one second etch step per minute.

FIG. 6 schematically illustrates two timing diagrams of example methods of etching a target material where both the total first etch time and the total second etch time are the same between the two timing diagrams, but the number of second etch steps is varied in accordance with embodiments of the invention. The methods of FIG. 6 may be specific implementations of other methods described herein, such as the method of FIG. 3, for example. Similarly labeled elements may be as previously described.

Referring to FIG. 6, a method 600 is similar to the method 500, but demonstrates varying the number of second etch steps without varying the total first etch time or the total second etch time. Specifically, a first configuration 601 repeats a cycle 650 that includes a first etch step using first precursor gas 641 and a first etch step duration 651 along with a second etch step using a second precursor gas 642 and a second etch step duration 652. The first configuration 601 has eight first etch steps and seven second etch steps, as shown.

In the second configuration 602, the number of second etch steps is reduced to two resulting in only three first etch steps. To keep the total first etch time the same and the total second etch time the same, both the first etch steps and the second etch steps are lengthened to a first etch step duration 656 and a second etch step duration 657 resulting in a much longer cycle 655. This scenario may be desirable when the total second etch time desired is known or capped and the other desired outcomes can be met even with reduced second etch step frequency.

FIG. 7 qualitatively illustrates example dimples exhibiting greater defects contrasted with example dimples exhibiting lesser defects in accordance with embodiments of the invention. For example, FIG. 7 may be used as a specific qualitative example for visualizing the possible advantages regarding defects transferred to an underlying layer afforded by the methods of this disclosure.

Referring to FIG. 7, a qualitative illustration 700 of two underlying layers is provided with one underlying layer 701 showing dimples 77 with greater defects and another underlying layer 702 showing dimples 78 with lesser defects. Although the goal is to transfer a highly regular (e.g. circular) dimple into an underlying layer, this ideal result may not be attainable in practice. Therefore, the example dimples are provided to demonstrate the differences between greater defects, such as high degrees of distortion and CER in the dimples 77, and lesser defects, such as the quasi-circular shapes with smooth edges in the dimples 78.

Dimples 78 are much closer than the dimples 77 to the ideal perfectly circular dimple 28 shown as transferred into the underlying layer 18 when no secondary facet 23 is present in FIG. 1. The dimples 78 are much more smooth (e.g. lower CER), much more uniform (e.g. lower distortion), and much larger (e.g. greater B/T ratio resulting in larger dimple sizes that more accurately reflect the desired pattern.

FIGS. 8A-8B illustrate example methods of etching a target substrate in accordance with embodiments of the invention. The methods of FIGS. 8A-8B may be combined with other methods and performed using the systems and apparatuses as described herein. For example, the methods of FIGS. 8A-8B may be combined with any of the embodiments of FIGS. 1-6. Although shown in a logical order, the arrangement and numbering of the steps of FIGS. 8A-8B are not intended to be limited. The method steps of FIGS. 8A-8B may be performed in any suitable order or concurrently with one another.

Referring to FIG. 8A, step 810 of a method 801 of etching a target material performs a first etch step to etch a target material of a substrate comprising a patterned mask disposed over the target material and having openings in the patterned mask. Performing the first etch step of step 810 comprises generating a first plasma to form a first passivation layer comprising a polymer material over sidewalls of the openings and etch the target material. Step 820 of the method 801 of etching the target material performs a second etch step to remove a portion of the first passivation layer. Performing the second etch step of step 820 comprises generating a second plasma from a tungsten containing precursor gas and exposing the substrate to the second plasma. The method 801 is then cyclically performed by repeating step 810 and step 820 as indicated by step 830.

Now referring to FIG. 8B, step 850 of a method 802 of etching a target material etches a target material with a first plasma, a substrate comprising a patterned mask disposed over the target material and having openings in the patterned mask. The etching of the target material in step 850 comprises forming a first passivation layer comprising a polymer material over sidewalls of the openings while etching the target material. Step 860 of the method 802 of etching the target material etches, with a second plasma, a part of the first passivation layer deposited in the etching of the target material and deposits a second passivation layer comprising tungsten. The method 802 is then cyclically performed by repeating step 850 and step 860 as indicated by step 870.

In various embodiments, the etch of the part of the first passivation layer in step 860 of the method 802 and the portion of the first passivation layer removed in step 820 of the method 801 may be the clearing of the openings described as the second etch steps of the method 300 illustrated in FIG. 3. Similarly, step 810 of the method 801 and step 850 of the method 802 may be the first etch steps of the method 300 illustrated in FIG. 3.

Example embodiments of the invention are described below. Other embodiments can also be understood from the entirety of the specification as well as the claims filed herein.

Example 1. A method of plasma etching a substrate includes cyclically performing a first etch step to etch a target material, the substrate including a patterned mask disposed over the target material and having openings in the patterned mask, performing the first etch step including generating a first plasma from a carbon containing precursor gas and exposing the substrate to the first plasma to form a first passivation layer and etch the target material, the first passivation layer including a polymer material over sidewalls of the openings. And the method further includes cyclically performing a second etch step to remove a portion of the first passivation layer, performing the second etch step including generating a second plasma from a tungsten containing precursor gas and exposing the substrate to the second plasma.

Example 2. The method of example 1, where the second plasma is further generated from a precursor gas mixture including nitrogen (N₂) and hydrogen (H₂), and where the tungsten containing precursor gas includes tungsten fluoride (WF₆).

Example 3. The method of one of examples 1 or 2, where the second plasma is further generated from a precursor gas mixture including oxygen (O₂), and carbonyl sulfide (COS), and where the tungsten containing precursor gas includes tungsten fluoride (WF₆).

Example 4. The method of one of examples 1 to 3, where the second plasma is further generated from a precursor gas mixture including oxygen (O₂) and where the tungsten containing precursor gas includes tungsten fluoride (WF₆).

Example 5. The method of one of examples 1 to 4, where the patterned mask includes an amorphous carbon layer (ACL).

Example 6. The method of one of examples 1 to 5, where the carbon containing precursor gas includes a fluorocarbon.

Example 7. The method of one of examples 1 to 6, where the second etch step is performed after the first etch step without an intervening purge step.

Example 8. The method of one of examples 1 to 7, where the second etch step forms a second passivation layer including tungsten over the patterned mask.

Example 9. The method of one of examples 1 to 8, where the first etch step is performed for a first duration and the second etch step is performed for a second duration, the second duration being shorter than the first duration.

Example 10. The method of one of examples 1 to 9, further includes performing an intervening step between the first etch step and the second etch step, where, during the intervening step, the carbon containing precursor gas and the tungsten containing precursor gas are concurrently injected.

Example 11. A method of plasma etching a substrate includes cyclically etching a target material with a first plasma, the substrate including a patterned mask disposed over the target material and having openings in the patterned mask, the etching of the target material including forming a first passivation layer including a polymer material over sidewalls of the openings while etching the target material. And the method further includes cyclically etching, with a second plasma, a part of the first passivation layer deposited in the etching of the target material and depositing a second passivation layer including tungsten.

Example 12. The method of example 11, where the second plasma is generated from a precursor gas mixture including nitrogen (N₂), hydrogen (H₂), and tungsten fluoride (WF₆).

Example 13. The method of one of examples 11 or 12, where the second plasma is generated from a precursor gas mixture including oxygen (O₂), carbonyl sulfide (COS), and tungsten fluoride (WF₆).

Example 14. The method of one of examples 11 to 13, where the second plasma is generated from a precursor gas mixture including oxygen (O₂) and tungsten fluoride (WF₆).

Example 15. The method of one of examples 11 to 14, where the patterned mask includes an amorphous carbon layer (ACL).

Example 16. The method of one of examples 11 to 15, where the first plasma is generated from a precursor gas mixture including a fluorocarbon.

Example 17. The method of one of examples 11 to 16, where the etching with the second plasma is performed after the etching with the first plasma without an intervening purge step.

Example 18. The method of one of examples 11 to 17, where the etching with the first plasma is performed for a first duration and the etching with the second plasma is performed for a second duration, the second duration being shorter than the first duration.

Example 19. A plasma etching system includes a plasma chamber, a substrate holder disposed in the plasma chamber and configured to support a substrate, and a controller operationally coupled to the plasma chamber and coupled to a memory storing a program to be executed in the controller, the program including instructions to cyclically generate a first plasma to etch a target material from a carbon containing precursor gas and form a first passivation layer including a polymer material over sidewalls of the openings, and generate a second plasma from a tungsten containing precursor gas to remove a portion of the first passivation layer.

Example 20. The plasma etching system of example 19, where the instructions include instructions to generate the second plasma from a precursor gas mixture including nitrogen (N₂), hydrogen (H₂), and the tungsten containing precursor gas, and where the tungsten containing precursor gas includes tungsten fluoride (WF₆).

Example 21. The plasma etching system of one of examples 19 or 20, where the instructions include instructions to generate the second plasma from a precursor gas mixture including oxygen (O₂), carbonyl sulfide (COS), and the tungsten containing precursor gas, and where the tungsten containing precursor gas includes tungsten fluoride (WF₆).

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of plasma etching a substrate, the method comprising cyclically:
performing a first etch step to etch a target material, the substrate comprising a patterned mask disposed over the target material and having openings in the patterned mask, performing the first etch step comprising generating a first plasma from a carbon containing precursor gas and exposing the substrate to the first plasma to form a first passivation layer and etch the target material, the first passivation layer comprising a polymer material over sidewalls of the openings; and
performing a second etch step to remove a portion of the first passivation layer, performing the second etch step comprising generating a second plasma from a tungsten containing precursor gas and exposing the substrate to the second plasma.

2. The method of claim 1, wherein the second plasma is further generated from a precursor gas mixture comprising nitrogen (N₂) and hydrogen (H₂), and wherein the tungsten containing precursor gas comprises tungsten fluoride (WF₆).

3. The method of claim 1, wherein the second plasma is further generated from a precursor gas mixture comprising oxygen (O₂), and carbonyl sulfide (COS), and wherein the tungsten containing precursor gas comprises tungsten fluoride (WF₆).

4. The method of claim 1, wherein the second plasma is further generated from a precursor gas mixture comprising oxygen (O₂) and wherein the tungsten containing precursor gas comprises tungsten fluoride (WF₆).

5. The method of claim 1, wherein the patterned mask comprises an amorphous carbon layer (ACL).

6. The method of claim 1, wherein the carbon containing precursor gas comprises a fluorocarbon.

7. The method of claim 1, wherein the second etch step is performed after the first etch step without an intervening purge step.

8. The method of claim 1, wherein the second etch step forms a second passivation layer comprising tungsten over the patterned mask.

9. The method of claim 1, wherein the first etch step is performed for a first duration and the second etch step is performed for a second duration, the second duration being shorter than the first duration.

10. A method of plasma etching a substrate, the method comprising cyclically:
etching a target material with a first plasma, the substrate comprising a patterned mask disposed over the target material and having openings in the patterned mask, the etching of the target material comprising forming a first passivation layer comprising a polymer material over sidewalls of the openings while etching the target material; and
etching, with a second plasma, a part of the first passivation layer deposited in the etching of the target material and depositing a second passivation layer comprising tungsten.

11. The method of claim 10, wherein the second plasma is generated from a precursor gas mixture comprising nitrogen (N₂), hydrogen (H₂), and tungsten fluoride (WF₆).

12. The method of claim 10, wherein the second plasma is generated from a precursor gas mixture comprising oxygen (O₂), carbonyl sulfide (COS), and tungsten fluoride (WF₆).

13. The method of claim 10, wherein the second plasma is generated from a precursor gas mixture comprising oxygen (O₂) and tungsten fluoride (WF₆).

14. The method of claim 10, wherein the patterned mask comprises an amorphous carbon layer (ACL).

15. The method of claim 10, wherein the first plasma is generated from a precursor gas mixture comprising a fluorocarbon.

16. The method of claim 10, wherein the etching with the second plasma is performed after the etching with the first plasma without an intervening purge step.

17. The method of claim 10, wherein the etching with the first plasma is performed for a first duration and the etching with the second plasma is performed for a second duration, the second duration being shorter than the first duration.

18. A plasma etching system comprising:
a plasma chamber;
a substrate holder disposed in the plasma chamber and configured to support a substrate; and
a controller operationally coupled to the plasma chamber and coupled to a memory storing a program to be executed in the controller, the program comprising instructions to cyclically
generate a first plasma to etch a target material from a carbon containing precursor gas and form a first passivation layer comprising a polymer material over sidewalls of the openings, and
generate a second plasma from a tungsten containing precursor gas to remove a portion of the first passivation layer.

19. The plasma etching system of claim 18, wherein the instructions comprise instructions to generate the second plasma from a precursor gas mixture comprising nitrogen (N₂), hydrogen (H₂), and the tungsten containing precursor gas, and wherein the tungsten containing precursor gas comprises tungsten fluoride (WF₆).

20. The plasma etching system of claim 18, wherein the instructions comprise instructions to generate the second plasma from a precursor gas mixture comprising oxygen (O₂), carbonyl sulfide (COS), and the tungsten containing precursor gas, and wherein the tungsten containing precursor gas comprises tungsten fluoride (WF₆).
